(19) United States
(12) Patent Application Publication
(10) Pub. No.: US 2025/0216440 A1
(43) Pub. Date: Jul. 3, 2025

(54) RELIABILITY TESTING USING FUNCTIONAL DEVICES

(71) Applicant: Octavo Systems LLC, Sugar Land, TX (US)

(72) Inventors: Masood MURTUZA, Sugar Land, TX (US); Erik James WELSH, Bellaire, TX (US); Gene Alan FRANTZ, Sugar Land, TX (US)

(73) Assignee: Octavo Systems LLC, Sugar Land, TX (US)

(21) Appl. No.: 18/867,298

(22) PCT Filed: May 18, 2023
(86) PCT No.: PCT/US2023/022777

§ 371 Date: Nov. 19, 2024

Related U.S. Application Data
(60) Provisional application No. 63/344,187, filed on May 20, 2022.

(51) Int. Cl. G01R 31/28

(52) U.S. Cl. CPC G01R 31/2817; G01R 31/2808

(57) ABSTRACT

Devices and methods are provided for using production devices during environmental testing. The structural and electrical integrity of external electrical connectors of a production device are determined, for instance, for board level reliability or second level solder joint reliability tests. Operational characteristics or internal connections of the production device can be monitored during testing.

### CROSS-REFERENCE TO RELATED APPLICATION

The present application claims priority to U.S. Provisional Application No. 63/344,187,filed on May 20, 2022, the disclosure of which is incorporated herein in its entirety by reference.

### TECHNICAL FIELD

Disclosed are embodiments related to reliability testing for semiconductor devices and packages, and in particular, reliability testing using a production device.

### BACKGROUND

The connection between a ball grid array (BGA) device and its system printed circuit board (PCB) is typically made by the end user. The reliability of this joint regarding electromigration, thermomechanical, impact, or vibration stress depends on several factors such as pad design in a PCB, ball material for a device, solder composition, and mechanical properties of the package and PCB. Given these many variables, devices can be tested to ensure the reliability of these joints. For instance, board level reliability (BLR) or 2nd level solder joint reliability tests (SJRT) may be used to determine the capability of solder joints, typically in a ball grid array (BGA), to resist electromigration, thermomechanical, impact, or vibration stress. Typically, this is done using special test “daisy chain” devices (DCDs) which are of the same size as the product in question, but are internally configured to allow testing of solder joints using simple continuity testers in combination with a test PCB. Design and fabrication of daisy chain devices and test PCBs can incur significant time and cost. Moreover, as the DCDs cannot be powered either during the test or after the test, the functional aspects of a production device cannot be tested at all.

Accordingly, there remains a need for improved methods and devices for reliability testing.

### SUMMARY

According to embodiments, a testing method is provided that comprises attaching a production device to a board and performing environmental testing on at least one of the production device and/or the board.

According to embodiments, a manufacturing method is provided that comprises: manufacturing a production device; mounting the production device on a testing structure of a production line (e.g., inserting onto a load board); and performing environmental testing on the mounted production device. In some embodiments, the mounting is a temporary mounting comprising non-permanent electrical and mechanical connections between the production device and the testing structure.

According to embodiments, a system is provided that comprises a test board and a production device mounted to the test board. According to some embodiments, a test board is provided. The test board may comprise, for instance, a board (e.g., substrate); a plurality of connection pads (e.g., for mounting a production device); and a plurality of test points arranged for one or more of: (i) measurement of an electrical connection between the board and a production device; and/or (ii) measurement of a signal or function of a production device mounted on the board. The system and/or test board may be used, for instance, with one or more of the foregoing methods.

### BRIEF DESCRIPTION OF THE DRAWINGS

The accompanying drawings, which are incorporated herein and form part of the specification, illustrate various embodiments.

FIGS. 1A, 1B, 1C and 1D depict examples of a test board using a dummy test device to create a daisy chain test structure for testing.

FIG. 2 illustrates a populated System in Package (SiP) device according to embodiments.

FIGS. 3A and 3B illustrate a Board Level Reliability Board (BLRB) for testing a production device.

FIG. 4 illustrates an external connector ball arrangement of a SiP device for testing a production SiP according to embodiments.

FIGS. 5A, 5C, and 5D illustrate example layouts for a board level reliability board using a functional production device for testing in accordance with embodiments. FIG. 5B is a table identifying board pads and corresponding device external connectors.

FIG. 6A illustrates a schematic diagram of a structural test board with a production device under test according to embodiments. FIG. 6B is a schematic diagram of a testing setup according to embodiments.

FIGS. 7A and 7B are flow charts illustrating a process according to embodiments. In certain aspects, FIGS. 7A and 7B depict methods for structurally and thermally testing a production device under test.

FIG. 8 is an illustration of a break-out board for testing a SiP device according to embodiments. In certain aspects, FIG. 8 depicts an example of a non-traditional break-out board for testing a SiP device in accordance with embodiments.

FIG. 9 is an illustration of a production line test setup according to embodiments. In some embodiments, FIG. 9 is depicts a setup for testing a production device using a board in accordance with embodiments.

FIG. 10 is a flow chart illustrating a process according to embodiments.

### DETAILED DESCRIPTION

Many semiconductor (S/C) devices use a ball grid array for external attachment to a PCB or other substrate. The device can be interconnected to other components located on a PCB to form a system. Systems may employ multiple S/C devices, packaged and unpackaged, operatively interconnected via the PCB. It may be important for a production system created on a substrate (or PCB) that its components are connected to the system substrate in a manner that provides structural and electrical integrity regardless of the environmental conditions to which that production system may be subjected. One type of environmental condition test is to subject a representation of the production system (and its associated substrate) to mechanical shock, vibrations, acceleration, and/or deceleration. Moreover, the vibrations that occur at different frequencies may result in resonant frequencies for the test board and test device, and resonant may be used to accelerate the test and reduce test time. Resonant frequencies stress the integrity of the connections between the test board and test device.

For an encapsulated packaged device/system, where the package also includes a substrate, it is difficult to test the attachments of the components located inside the package to the substrate, or the substrate external connections to its system PCB or other substrate. One such packaged production system, by way of example, is a System in Package (SiP) device.

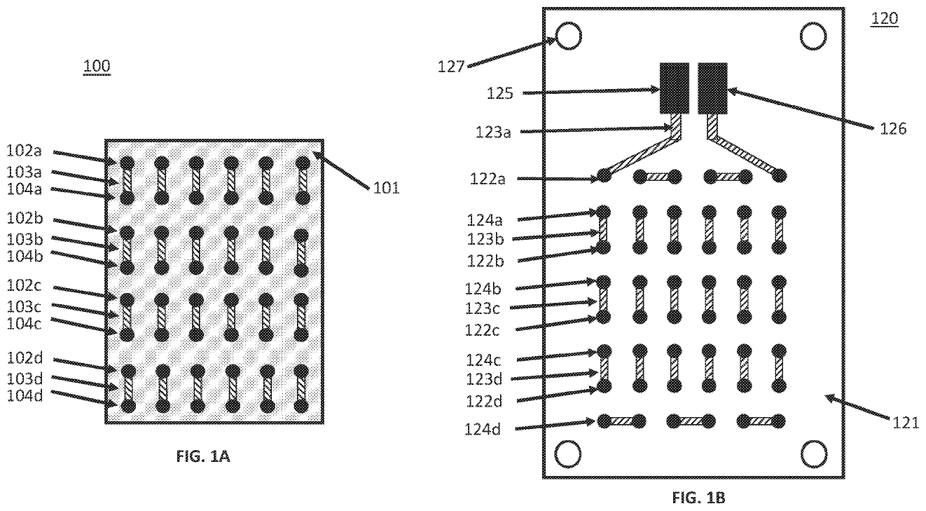

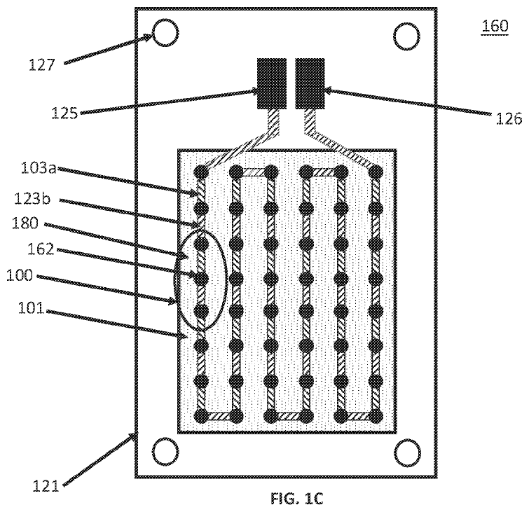

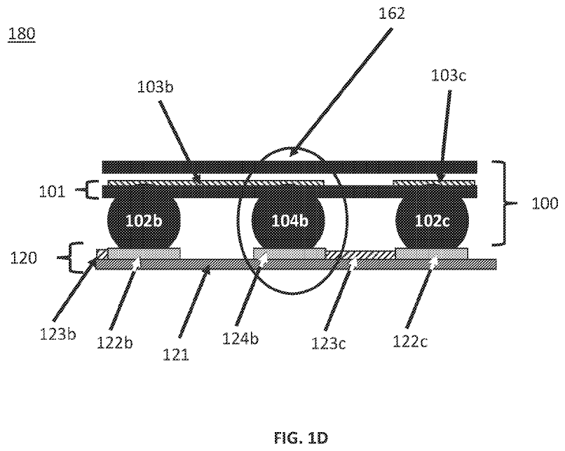

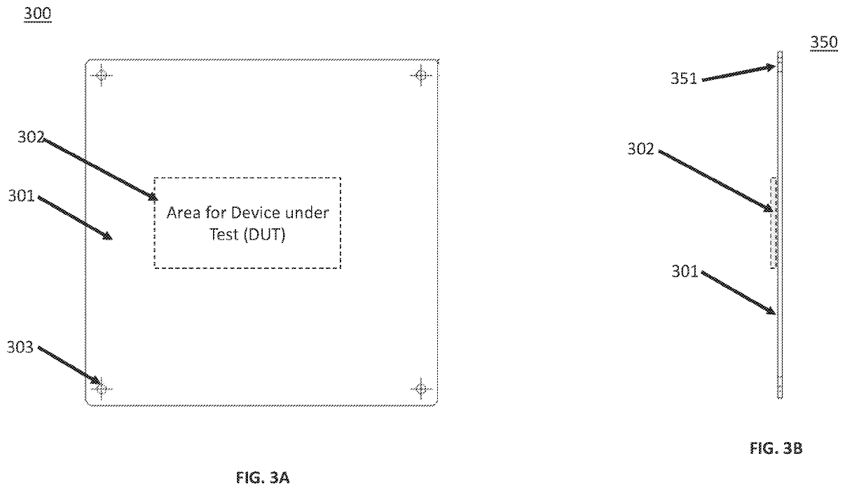

The testing of the substrate connections to a PCB can be performed by substituting or representing a packaged or unpackaged device or system with a special test device/system substrate that is the same size and weight, with the same external connector pattern, as the packaged device/system being tested on its special test PCB. This is illustrated, for example, in FIGS. 1A-1D and 3A-3B. This special test device/system substrate has no components mounted on it, and instead, has special internal connections specifically for testing the structural and electrical integrity of the connections with its special test PCB. Aspects of the present disclosure provide for replacing this special test device/system with a production device and employing a different layout of the test board. This can overcome numerous challenges in the field.

For instance, the design and construction of a special test device/substrate and special matching test board is costly and imposes a time delay. Furthermore, the special test package, which can be referred to as a “daisy chain test device” (DCTD) or “test device,” is not identical to the production package. Differences may include, for example, pad structure, mechanical and electrical integrity of the internal vias and traces, weight distribution, thermal and electrical integrity of the components, etc. Further, a DCTD cannot be operated in the same way as production devices during environmental testing. Thus, some important aspects of the actual production device package may not be represented in any environmental stress test.

In addition, a DCTD cannot be attached to the production PCB of an actual production device for testing. Accordingly, a special daisy chain board level reliability-test board (DCBLRB), which is representative of the actual board, substrate, or PCB of a production device under test (PDUT), is designed to allow for mounting the DCTD in a manner to complete the connections needed for a daisy chain. That is the DCTD is mounted on its own special daisy chain board level reliability-test board (DCBLRB), as part of the simulation of a final product, and to which it is securely and electrically attached.

According to embodiments, a BLRB board as described herein takes signals from a series of external connectors of a production device under test (PDUT) and brings them out using an electrical connector or conductive trace on the BLRB that runs from a desired external connector under the production device to a larger connector (e.g., a test point) on the BLRB that is less congested, for easier connections to that PDUT device (rather than a “simulated test device under test” (STDUT) for attaching test signals). In certain aspects, the external connectors are typically congested (e.g. a high density ball grid array). Also, the desired external connector may be a ball in the ball grid array.

Regarding FIGS. 1A-1D, an example of a test board using a dummy device to create a daisy chain is illustrated. In this example, one link of the chain in a daisy chain setup is inside the test device, and makes a connection between two adjacent exterior connectors inside the test device, with the next link in the chain being a conductive path from one of the pads on the test board to the next pad on the test board. That is, links of the chain alternate between those in the device corresponding to exterior connectors and the pads on the test board to form a serial chain. Thus, the daisy chain is “broken” when one or more of the physical and electrical links corresponding to exterior connecters of the device being tested to a pad on the test board is no longer making an electrically conductive connection. However, certain embodiments of the present disclosure do not have the limitations of traditional approaches to testing. For instance, aspects of the disclosure describe design modifications for a production device to provide additional test connections that are not part of a daisy chain and may be placed at locations on the substrate of a production device that have traditionally been subjected to failure during board level reliability (BLR) or 2nd level solder joint reliability tests (SJRT).

In the examples shown in FIGS. 1A-1D, the daisy chain configuration can detect only one disconnect between the DCBRLB and the simulated test device under test (STDUT, and sometimes referred to herein as a DCD). One link 103 of the chain is inside the test device 100 and makes a connection between two adjacent exterior connectors 102, 104 inside the test device, with the next link in the chain being a conductive path from one of the pads 124a on the test board 121 to the next pad 122b on the test board 121. The links of the chain alternate between those in the device 100 corresponding to exterior connectors (connected to pads on the test board) and the pads on the test board (DCBLRB) 121 to form a serial chain.

Failures of the array of external connectors to a PCB during normal use will typically be concentrated in specific areas of the ball array. Typical areas in the array that have connection failures are, for example, the corners of the array and the center of the array. Existing daisy chain methods are not well suited for detecting such failures during board level Reliability (BLR) or 2nd level solder joint reliability tests (SJRT). The way a daisy chain structure is set up, it detects a ball connection failure. But once a connection failure is noted it is very difficult to identify which one, or how many more, balls have failed. In other words, the daisy chain test results in a pass or fail, but there is no way to determine which ball has failed, of if more than one ball failed. This issue can be addressed by some embodiments of this disclosure. Other benefits include the cost of developing a test device or STDUT, the exactness of simulating the form, fit, and function of a production device, the inability to instrument or test the device while powered up and running programs, and inability of testing internal components in the production device under test (PDUT). Additionally, there is the cost of designing and developing the DCBLRB. One or more embodiments may eliminate the need for such a special test substrate (DCBLRB) and allow for performing selected portions of the tests using a production device. Further, embodiments allow an exact production device to be used in an environmental stress test. In this manner, embodiments can provide for improved reliability testing of production devices and systems.

According to some embodiments, every BGA ball or other external connector that is connected to any electrically conductive plane or trace in the production device and connected to a pad on the BGA may potentially be used to test joints related to those balls. By testing pairs (or other multiple combinations) of those balls that are connected to the same plane of the production device at the time of testing, a substantial number of internal vias and external solder joints on the BGA may be tested while avoiding the expense of tooling up or developing a special test package to emulate or otherwise mimic the mechanical characteristics of the device of interest. Beyond testing the integrity of the balls or other external connectors, the integrity of the inter-layer connection vias of the substrate of a packaged device may also be tested.

Referring again to FIGS. 1A, 1B, 1C and 1D, examples of daisy chain techniques are illustrated, which are used as part of testing the mechanical and electrical integrity of a simulated device's external connectors with its PCB. These examples employ an array of connection balls, including 102(a,b,c,d) and 104(a,b,c,d) as the external connectors connected together with conductive traces 103(a,b,c,d) for a STDUT. The structure includes a packaged device 100 with a substrate 101 attached to a printed circuit board (PCB) 121 of the test board 120. A top view of a daisy chain test device 100 of FIG. 1A attached to the PCB 121 is depicted in FIG. 1C. Once attached to the PCB, the daisy chain-like connection is completed as depicted in FIGS. 1C and 1D. Again, one link of the chain is inside the STDUT and makes a connection between two adjacent exterior connectors inside the STDUT, with the next link in the chain being a conductive path from one of the pads on the DCBLRB test board 120 to the next pad on the test board; that is, links of the chain alternate between those in the device 100 corresponding to exterior connectors and the pads on the test board 120 to form a serial chain.

Referring now to FIG. 1A, a top down, through view of a test device 100 (STDUT) that has been designed such that each of the external connectors 102 is electrically connected to an adjacent connector 104 with a conductive trace 103 on the device's substrate 101. Traces 103, inside the test device 100, have a striped diagonal lines that are tilted to the let from vertical. The item numbers 102, 103, and 104 are used for all the external connectors and traces in FIG. 1A in a repeating fashion as they all perform the same function, but with additions of a, b, c, d, etc. to the item number to distinguish between physical locations. In this example, the test device 100 has been designed and assembled to represent, as close as possible, the form, fit, and function of the production device, for which it is a substitute in an environmental test.

FIG. 1B is a top-down view of a special test board 120 on which the daisy chain test device (STDUT) 100 is to be attached, for instance, as depicted in FIG. 1C. In this example, it has an array of landing pads 122 and 124 interconnected on the PCB 121 with electrically conductive traces 123. Traces 123 have a striped diagonal lines that are tilted to the right from vertical in this illustration. In this example, the test board 120 has two test points (TPs) 125 and 126 to give access to the daisy chain. Again, the item numbers 122, 123, and 124 are used for all the external connectors and traces in FIG. 1B in a repeating fashion as they all perform the same function, but with additions of a, b, c etc. to the item number to distinguish between physical locations. For completeness, the BLRB has mounting holes 127 in each of its corners to attach it to the test apparatus (not shown). Such testing apparatus are, for example, a vibration machine, thermal chamber, and shock machine. In some cases, it may be important to identify resonant frequencies that are destructive to the external connector interface with the PCB in actual use conditions of the final product, and using resonant frequencies can accelerate the test and reduce test time.

FIG. 1C depicts a top-down view of the completed BLR test structure 160 with the test device (STDUT) 100 electrically attached to the DCBLRB's 120,121. Once attached, the daisy chain is completed with the external connectors of the test package 102, 104 electrically and mechanically attached to the landing pads using a specified attachment processes. An example is shown with item 162 of FIG. 1D, which depicts both the test package external connector 104b and the PCB landing pad 124b. In this figures, the conductive traces continue to use the same striped diagonal lines employed in FIGS. 1A and B. The mounting holes 127 that are used to attach the completed test structure 160 to the test apparatus are also shown. In this example, a test can be performed to evaluate the mechanical and electrical integrity of the physical connection between a representative and exemplary ball 102 and pad 122, and similarly, the actual physical connection of ball 104 with pad 124.

FIG. 1D depicts a side view of a portion of the completed test structure of FIG. 1C. With reference to FIGS. 1A and 1B, the daisy chain in this example begins with the test point 125 on the DCBLRB 120. The test point 125 is electrically connected to the landing pad 122a on the PCB 121 via an electrical trace 123a. The landing pad 122a is attached to one pad of the test device's external connector 102a. External connector 102a is electrically attached to external connector 104a via a conductive trace 103a on the substrate 101 in the test device 100. External connector 104b is electrically attached to a second test point 126 via a landing pad 122d and conductive trace 123c. This series of connections continues for all the external connectors of device 100 and the pads of the PCB 121 and completes the electrical daisy chain circuit. If any one of the balls 102a/b or 104a/b (102a/b/c/d or 104a/b/c/d in FIG. 1A) detach from either the test device 100 or test board 120, the resistance between the two test points 125 and 126 changes from near zero ohms to a value much greater than zero ohms. The connection 162 between the DCBLRB 120 and the STDUT 100 is made via the landing pad 122b, ball 104a and the conductive trace 103a, in the substrate 101 of the DUT 100.

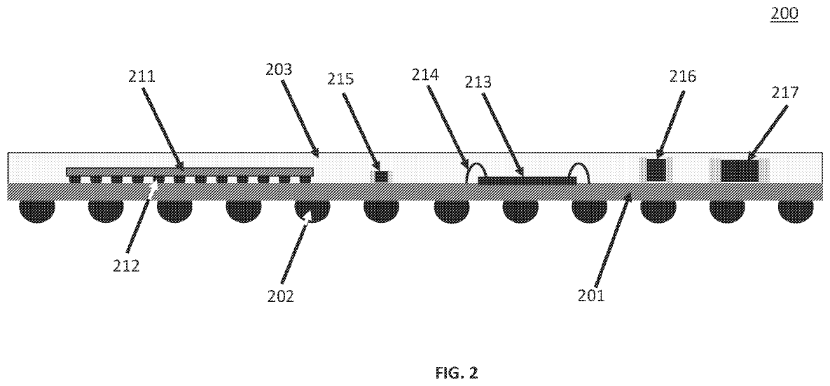

FIG. 2 illustrates an example of a populated SiP according to some embodiments. It may be, for example, the PDUT 200 that is either used in a test according to embodiments, or is replaced in the test with a dummy device (see FIGS. 1A, B, C, and D). In this example, the SiP includes a substrate 201 with connection balls 202, a device 211 attached to the substrate 201 with bumps 212, another device 213 attached to the substrate 201 and electrically connected via wire bonds 214, and several passive devices of different sizes 215, 216, and 217, which are all interconnected using conductive traces and vias in substrate 201. Other different and additional devices and components may be attached to the substrate of a SiP, although not depicted.

FIGS. 3A and 3B depict an example of a Board Level Reliability Board (BLRB) layout used in environmental stress testing of an integrated circuit package or device. FIG. 3A is a top view of the BLRB 301. Similar to the depiction in FIGS. 1A, B, and C, the PCB 301 in this example has an area 302 where a test device, such as device 100, can be be mounted. Additionally, attachment holes 303 (which are similar to openings 127 of FIG. 1C) are placed in the four corners of the PCB. FIG. 3B depicts the side view of a BLR PCB 351.

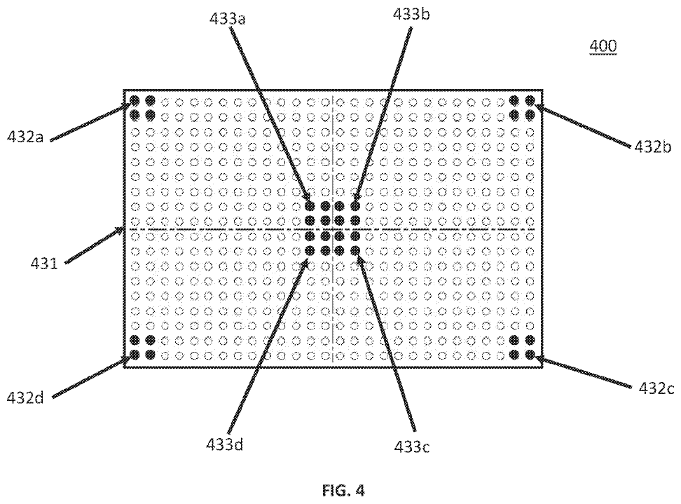

FIG. 4 depicts a set of balls or other external connectors 400 of a production device, such as a SiP, according to embodiments. In some embodiments, the subset of balls of interest are those in one of the four corners 432a/b/c/d of the ball map 431, and/or a subset of balls 433a/b/c/d found in the center of the ball map 431. These external connector locations are identified as they are the most likely locations for structural and electrical integrity issues. However, in certain aspects, all the external connectors (e.g., balls) of the device being tested may be attached to pads on a test board.

According to embodiments, a method is provided where environmental testing of a packaged device/component is done using production devices in lieu of emulated test specimens of the production device to obtain board level reliability (BLR) data on the structural and electrical integrity of the external connectors of the product. This testing is performed to give a high degree of confidence of the integrity of and reliability of solder joints between the external connectors of a packaged device/component and the circuit board (or PCB) to which they are connected. The qualification process of an integrated circuit package, for instance, can include temperature cycling, shock, and vibration tests to determine the structural and electrical integrity of the external electrical connectors attached to the device or package and the circuit board to which it is attached

In system in package (SiP) devices, many power, ground, and signal conductive planes or traces may be used to properly power and interconnect its internal active and passive components. These conductive planes or traces are attached to multiple external connectors, such as the balls of a BGA device. Aspects of the disclosure allow for a BLR circuit board to be designed to connect to various combinations of external connectors for power, ground, and input/output (I/O) signal, rather than a specific test device/package with external connectors partially connected together internally as part of a daisy chain. Ball grid arrays (BGAs) are used as examples herein, but other external connection structures, such as through hole, leaded, leadless, magnetic, and optical connectors can also be sued in embodiments.

In certain aspects, embodiments are disclosed that allow for some external connectors for various power rails, ground planes, and other input/output (I/O) signals to be selectively included as part of the set of external connectors monitored during environmental tests.

In certain aspects, embodiments are disclosed that allow for internal vias to be tested for structural and electrical integrity by defining electrical combinations of external connectors that are connected internally to different conductive layers in the component or device substrate, which are interconnected using vias (e.g., interconnections from one connection layer to another) or passive devices, such as resistors, capacitors, inductors, optical devices, or mechanical structures.

Powering a production device during the test, for instance, to be environmentally tested while performing normal operational/computational functions is also provided in some embodiments. Apparatuses for Board Level Reliability-test Boards (BLRBs) are also provided in accordance with the teachings of the present disclosure. Some BLRB test boards may be used in a non-traditional manner, and may be structured for a final test for high reliability production devices at the end of their production line before they are shipped to a customer.

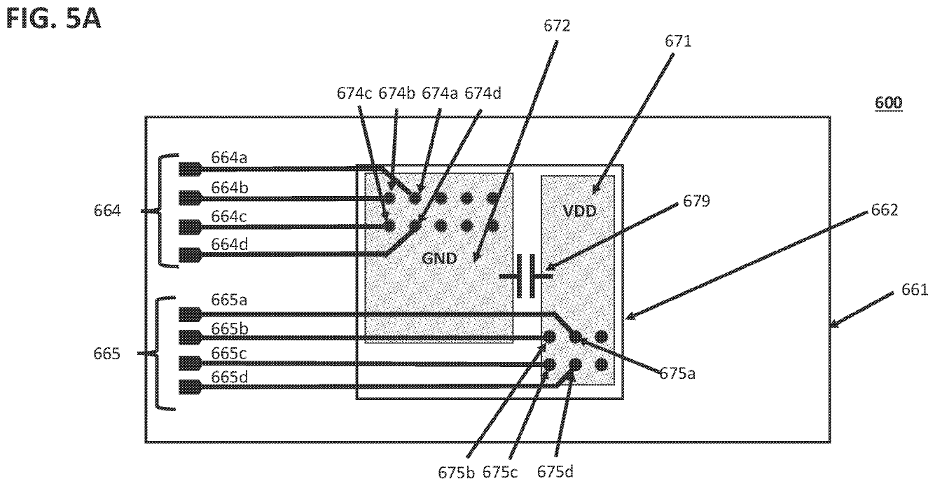

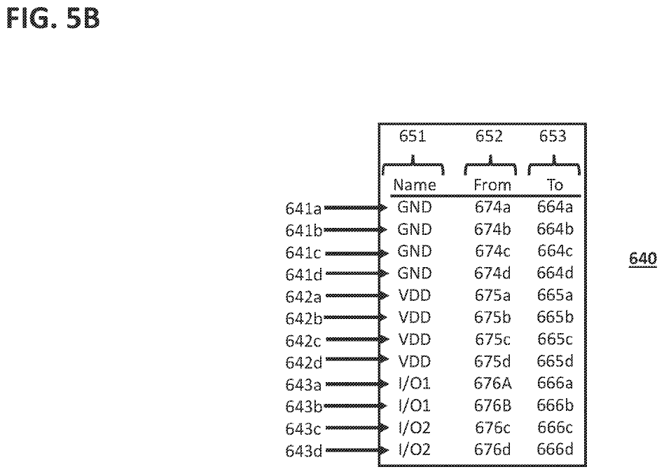

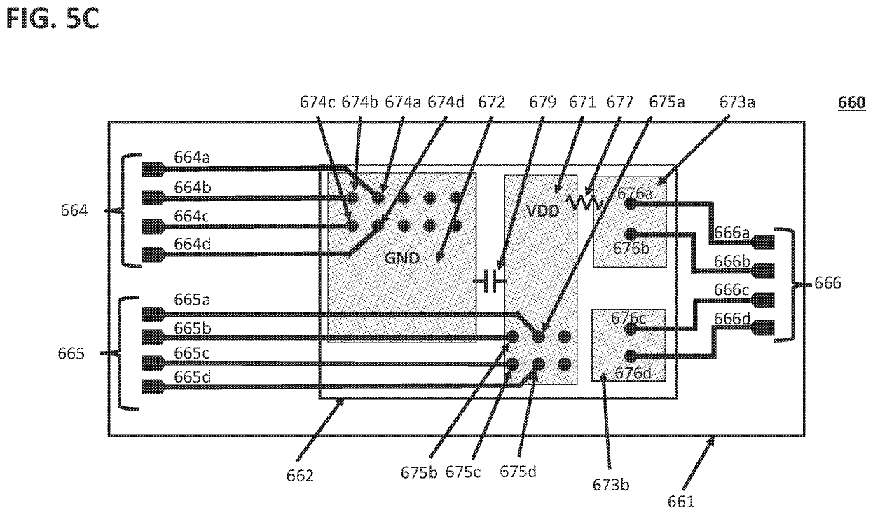

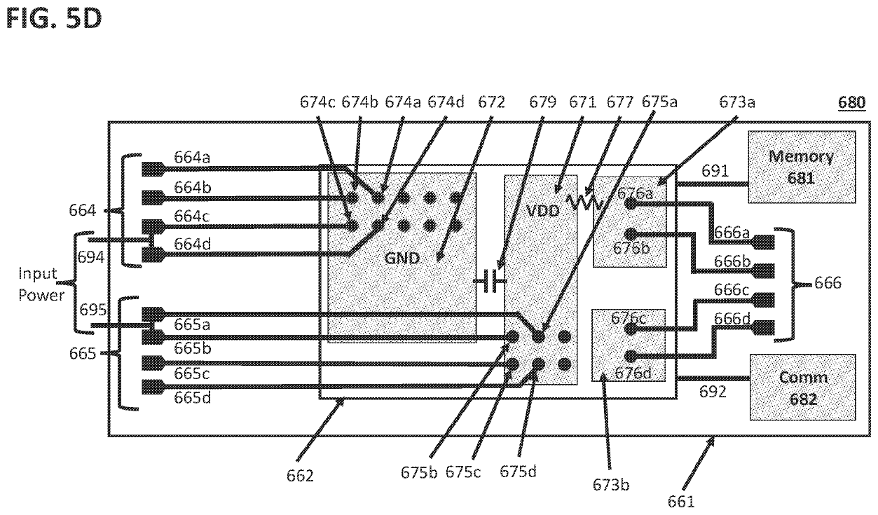

Referring now to FIG. 5A, a testing setup 600 is shown according to some embodiments. In this example, a BLRB 661 test structure (e.g., DCBLRB test board) is shown for use with a production packaged device 662 rather that a special test packaged device (STDUT) attempting to match the form, fit, and function of the production device under test (PDUT). FIGS. 5C and 5D depict similar structures. FIG. 5B is a table listing of test points and corresponding external connectors and their type of signal.

In certain aspects, FIGS. 5A, 5C, and 5D depict a through view of a physical representation of a portion of a simplified test board and an attached production device, such as a SiP, according to embodiments. In some embodiments, the production test device has a substrate with multiple layers for power (voltages), ground(s), and other types of signals, such as for example, input signals, output signals, test signals, and control signals. The layers may be the physical layers in a substrate, while planes may be a description of how conductive materials (e.g., that make up conductive traces or conductive pours inside the substrate) are arranged in the substrate. In certain aspects, planes in one physical layer may be separated by non-conducting physical layers from other physical layers. For example, a “plane” may include conductive traces or conductive pours on several different physical layers of a substrate and a physical layer may include multiple planes. In addition, some of the power planes may be referred to as a power rail. An example includes a “V1 rail”, where V1 is a specific voltage. In FIGS. 5A, 5C, and 5D, and according to some embodiments, items 674 and 675 are locations where the external connectors of the device under test are located on the test device 662 and where those connectors make a mechanical and electrical connection with a corresponding pad on the surface of the test board 661. Also, and according to some embodiments, items 664 and 665 are locations on the test board where test points are located adjacent the edges of the test board for ease of making connections for testing the device 661.

For instance, as shown in FIG. 5A, the test board extends connections between the external connectors of a device and the associated mounting pad on the test board from beneath the device and effectively moves this connection to the outer periphery of the test board. In certain aspects, the connections of the external connector locations at the corners and the center of the device are brought out to the edges of the test board for testing during environmental testing of the device. In addition, the test board can be mounted on a test apparatus (not depicted) for environmental testing of a device. According to embodiments, the test apparatus supplies the test board with sources of power and grounds and connections to the test points on the board. The output(s) of the test board are available at the interface of the board outputs and to any additional test equipment needed to test the device and the integrity of its external connections. In embodiments, the outputs are a plurality of various signals, measurements and voltages and may be adapted to be processed by automated test equipment or by a human interface or a combination of both.

FIG. 5A, according to embodiments, provides a functional example of how a power (VDD) 671 and a ground plane (GND) 672 of a production packaged device are electrically connected to external connectors 675a, b, c, and d, and 674a, b, c, and d, respectively, of the production device under test (PDUT) 662. The external connectors 675a/b/c/d and 674a/b/c/d are then electrically connected to test points 665a/b/c/d and 664a/b/c/d respectively on the BLRB 661. In this manner, external connectors 674a/b of PDUT 662 are electrically connected together internally through the GND plane 672. In addition, external connectors 675c/d are electrically connected together internally through the VDD plane 671 respectively in the DUT 662. By doing so, the electrical integrity of the external connectors 674a and b and 675c and d are monitored by testing the impedance through each of the pairs of test points 664a and b, and 665c and d, respectively. As a further example, alternative pairing may be used based on the capacitive coupling from the bulk capacitors 679 between the GND and VDD planes. Thus, a test pair may be created for an exterior test monitoring device between external connectors 675a and 674c, which are connected to test points 665a and 664c.

Alternatively, multiple serial interconnections may be created by connecting the external connectors 674c, 674d, 675a, and 675b by connecting 664d and 665a. In this example the two terminals of the serial interconnections would be test points (TPs) 664c and 665b. Another benefit of using a production device as the device under test (DUT) 662 to populate the BLR board 661 is the ability to have the DUT powered up and running during any test sequences.

FIG. 5B is a table listing of the type of signal, the origination of the signal at an external connector of the production device (by item number), and the connection to corresponding the test point (by item number) on the test board. In certain aspects, it may be representative of a subset of the production device under test's (PDUT's) external connectors that are internally connected as part of the digital ground plane (GND) 674a/b/c/d, power plane (VDD) 675a/b/c/d, or I/O signal plane 676a/b/c/d of the PDUT 662. In some embodiments, an I/O signal connector 676a/b/c/d can be paired with either a power 671a/b/c/d or ground 672a/b/c/d plane through a pull-up or pull-down resistor, as illustrated with element 677 of FIG. 5d, between the signal connector and an external connector in the power 671 or ground 672 plane respectively. In certain aspects, the list 640 is a segment of the design net list used to design and layout the BLR printed circuit board (PCB) depicted in FIGS. 5A, 5C, and 5D. In FIG. 5B, column 651 has the name of the signal to be connected (in this case GND, VDD, I/O1 and I/O2). The second column 652 lists the names of the external connector array connectors (in this example the ball names, e.g., 674a) of the PDUT that will be connected to the test points (TPs) of the BLR PCB listed in the third column 653. For example, the GND signal of row 641a is ball 674a on the PDUT and is connected to TP 664a in the array of TPs. In the same manner, rows 641a through 643d specify how each of the selected signals (column 651) is connected from the PDUT (column 652) to a specific TP (column 653).

In some embodiments, every external connector that is connected to a power 671, ground 672, or I/O signal plane 673 that has two or more external connector may be used to be part of a test pair, particularly in pairs of external connectors electrically attached to the same power 671, ground 672, or I/O signal plane 673 as illustrated in FIG. 5D. Using multiple different power 671, ground 672, and I/O signal planes could be used to extend the pair chains from two external connectors per interconnection to needing only one external connector connected to multiple other external connectors on the PDUT 662. For example, external connector 674a could be used to test external connectors 674b, 674c, and 674d separately and independently. In this instance, the resulting pairs would be 674a/b, 674a/c, and 674a/d.

By using production devices 662 as shown in FIG. SA, rather than special test packages 100 shown in FIG. 1A, the mechanical characteristics (e.g., the form, fit, and function characteristics) are identical to the production devices rather than just mimicking the characteristics.

FIG. 5C is a top though view 660 of a test board and an attached production device where the production device depicts four discrete planes, and thus, has additional test points and associated external connectors of the device. According to some embodiments, FIG. 5C includes the same GND 672 and VDD 671 connections 674a/b/c/d and 675a/b/c/d to test points 664 and 665, but also has signal 673a/b portions with connections 676a/b/c/d to test points 666a/b/c/d. Also, connections 676a/b are internally connected to VDD through a resistor 677. This resistance 677 could either be a pull up resistor as shown, or a pull-down resistor that is attached to GND rather than VDD. Finally, while in operation, either signal 673a or 673b may be connected to GND through a resistive, capacitive, or inductive load making it possible to bring them out and use them as test points. With these additional signal connectors 676a/b/c/d, new sets of paired test points—including more than 2 test points—may be created. Examples include 666a/b, 666c/d, 666a/665a, 666a/665b, 666a/665c, and 666b/665d.

FIG. 5D depicts a top through view 680 of a test board and an attached production device. Here, the production device depicts four discrete planes, and thus, has additional test points and associated external connectors of the device. In certain aspects, FIG. 5D depicts an example of how the PDUT 662 may be powered and functioning while under test according to some embodiments. In embodiments, a subset, or all, of the test points connected to GND 672, and test pins connected to VDD 671, are connected to a power input (VDD 695 and GND 694) to power the PDUT. A memory device 681 and an interface to a controller 682 are located on the board and connected to the PDUT allowing for the PDUT to download and run programs while being tested, and/or during pre and post-test evaluations. The test board may have more or fewer components on it to support powering up and running the PDUT; components exterior to the test board may be used to support powering up and running the PDUT.

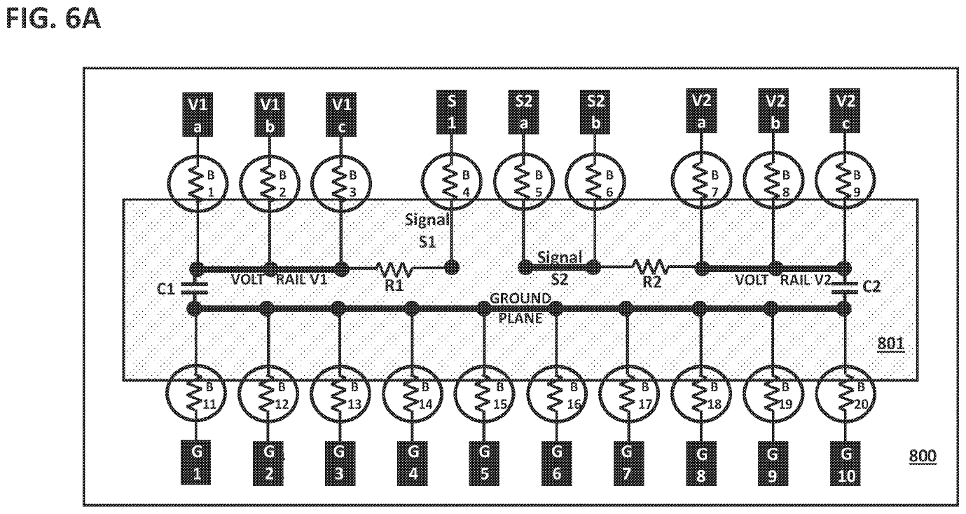

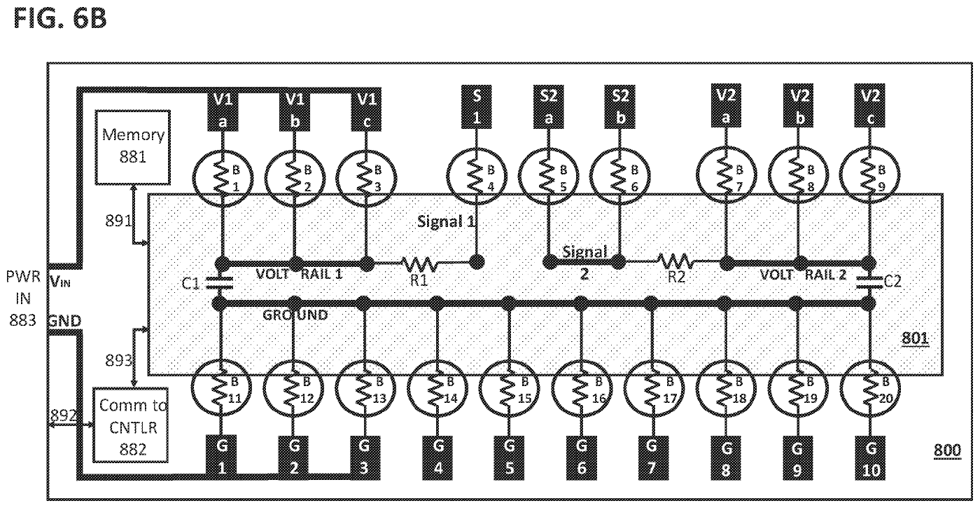

FIG. 6A is a partial electrical schematic representation of FIG. 5A, and depicts how testing may be performed using the test points of the test board in some embodiments. In this example, a structural test board 800 with a production device under test (PDUT) 801 is shown. The test board can have multiple test points G1/2/3/4/5/6/7/8/9/10, V1a/b/c, V2a/b/c, S1, and S2a/b. In this example, each test point is attached to a ball B1-20 attached to the PDUT 801. Internal to the PDUT, 10 balls (B11-20) are connected to the ground plane, 3 balls are connected to the V1 voltage rail, 3 balls are connected to the V2 voltage rail, two balls are attached to the S2 signal, and one ball is attached to the S1 signal. Further, a bulk capacitor C1 is connected to both the V1 voltage rail and the ground plane, a bulk capacitor C2 is connected to both the V2 voltage rail and the ground plane, a resistor RI is connected to both signal SI and voltage rail V1, and a resistor R2 is connected to both signal S2 and voltage rail V2. By way of illustration only, each of the balls is depicted in a circle with a resistor in that circle to illustrate the resistance from the ball to its connection inside the device. Ten balls (B11-20), which are attached to the ground plane, are connected to ten test pins (G1-10) in the example. Three balls (B1-3), which are attached to Voltage Rail V1, are connected to three test pins (V1a/b/c). Three balls (B7-9), which are attached to Voltage Rail V2, are connected to three test pins (V2a/b/c). One ball (B4), which is attached to Signal S1, is connected to test pin S1, and two balls (B5-6), which are attached to signal S2, are connected to test pins (S2a/b). With these interconnections, many pair wise connections can be made to monitor the structural and electrical integrity of the balls attached to the test pins. For example, test pairs could be G1/2, G1/3, G1/4, or G1/10, where G1 is common to all 4 of the test pairs. In this example, given that ball B11 is a known good connection between the PDUT 801 and the test PCB 800, balls B12/13/14/20 can be tested for structural and electrical integrity. Other examples of pair wise connections could be V1a/b, V1b/c, V2a/b, V2a/c, and S2a/b, testing balls B1, B3, B8, B9, and B6, given that B2, B7, and B5 are known good connections between the PDUT 801 and test PCB 800. Finally, examples of pair wise connections could be G1 and V1a, G10 and V2c, V2a and S2b, through capacitor C1, C2, and R2, respectively, testing the structural and electrical integrity of balls B1, B9, and S2a. However, multiple such connections may be made, as there is no restriction to only testing pairs of connections.

FIG. 6B is an electrical schematic representation of a structural test board similar to that of FIG. 6A, which further depicts how a PDUT 801 may be powered by connecting an appropriate number of GND connectors (in this example, G1/2/3) and VIN connectors (in this example, V1a/b/c) to an external power source 883 according to some embodiments. For the PDUT to be functional, it may also be connected to a memory block 881 and to a communication port 882 via links 892 and 893. The memory may be, for example, DDR, flash, or any combination thereof. In certain aspects, link 892 may be either wired or wireless. Wired links may include, for example, JTAG, USB, or Ethernet. Wireless links may include, for example, Bluetooth, WiFi, or optical. However, the device may receive software to operate the device from other external sources that are off the test board and additional components may be added to the test board to help with the operation of the device while being environmentally being tested.

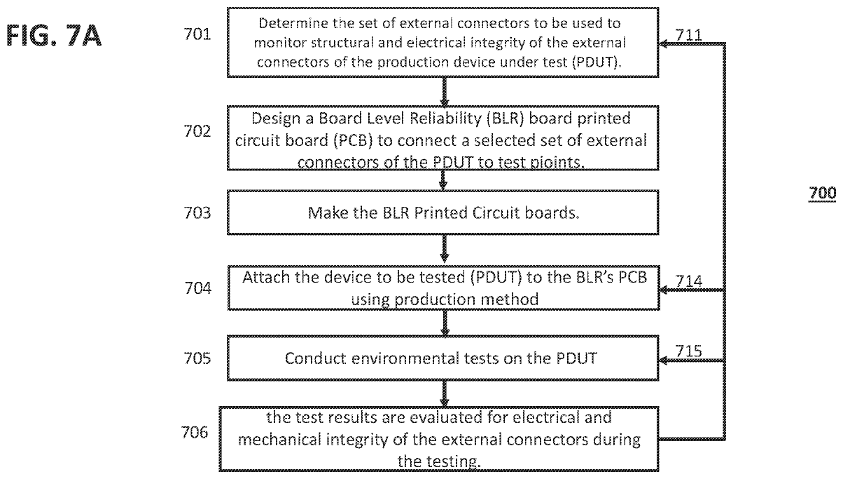

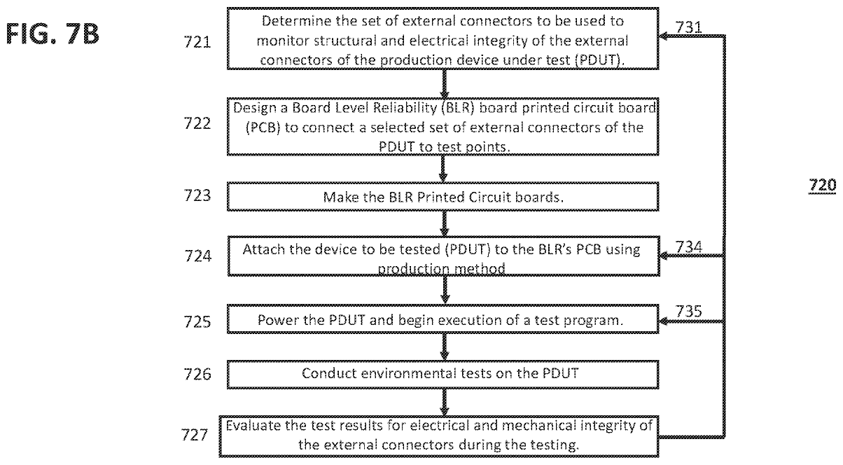

FIG. 7A depicts a process 700 for structural and thermomechanical testing of a production device according to some embodiments. The process may begin with step 701, in which the set of external connectors to be used to monitor structural and electrical integrity of the external connectors of the production device under test (PDUT) are determined. Next, step 702 is to design the board level reliability board's (BLRBs) printed circuit board (PCB) so that the set of external connectors selected in 701 are brought out to test points. The BLRB is manufactured in step 703. Next, in step 704, the PDUT is attached to the BLR board's PCB. This may be, for instance, using the same method used in attaching production devices to a system PCB. This is followed by the prescribed environmental testing (structural or thermomechanical) in step 705. Finally, in step 706, the test results are evaluated for electrical and mechanical integrity of the external connectors during the testing.

Once the test results have been evaluated for electrical and mechanical integrity of the external connectors during the test 706, multiple additional steps may be taken according to some embodiments. For example, the next step may be conducting another environmental test of the same PDUT 715, or the next step 714 may be attaching a second PDUT to a BLR's PCB 704 and conducting an environmental test on the PDUT 705 followed by evaluation in step 706. In some embodiments, the next step 711 may be to determine a new set of external connectors to be used 701, followed by repeating the following steps depicted in this method 700. The final next step would be to conclude the test. According to embodiments, one or more of steps 701-706, 711, 714, and 715 may be optional.

FIG. 7B depicts a method 720 for structural and thermomechanical testing of a production device, while powered up, according to embodiments. In some embodiments, the first step 721 is to determine the set of external connectors to be used to monitor structural and electrical integrity of the external connectors of the production device under test (PDUT). Next, step 722 is to design the board level reliability board's (BLRBs) printed circuit board (PCB) so that the set of external connectors selected in 721 are brought out to test points. The BLRB is manufactured in step 723 Next, in step 724, the PDUT is attached to the BLR board's PCB (e.g., using the same method used in attaching production devices to a system PCB). The PDUT is then powered up and booted in step 725. This is followed by the prescribed environmental testing (structural or thermomechanical) being conducted in step 726. Finally, in step 727, the test results are evaluated for electrical and structural integrity.

Once the test results have been evaluated for electrical and mechanical integrity of the external connectors during the test in step 727, further steps may be taken. For example, the next step may be conducting another environmental test of the same PDUT 735; or the next step 734 may be attaching a second PDUT to a BLR's PCB 724, powering the PDUT and begin the execution of a test program in step 725 and conducting an environmental test on the PDUT 726 followed by evaluation in step 727. Finally, the next step 731 may be to determine a new set of external connectors to be used in step 721, followed by repeating the steps depicted in this method 720. According to embodiments, one or more of steps 721-727, 731, 734, and 735 may be optional.

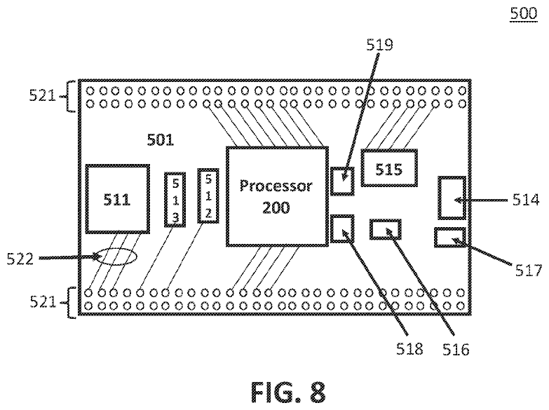

FIG. 8 depicts a board according to embodiments. In certain aspects, FIG. 8 depicts an example of a non-traditional break-out board for testing a SiP device in accordance with embodiments. The BRLB may, if needed, also serve as a breakout board 500. According to embodiments, a breakout board 500 is used during development of a system level product using a production device 200. A breakout board may have, for example, additional components attached to the PCB 501. Such components may be, for example, several other components: a micro-SD card 511, a micro-USB port 514 for power and communications needed to properly connect to and operate the production device 200, a JTAG port 513, and/or boot/EPROM memory 515 to configure the production device 200, and to easily connect to various experiments (not shown) using standard connectors attached using test pins/points 521. In this example, test points 521 are attached to the appropriate external connectors of the production device 200 via conductive traces 522 on and in the breakout board 500. Test points 521 provide input/output voltages, grounds, and signals. These connection points may be needed for operation and emulation of a production device. Other included components may be a reset button 516, LEDs 518, an I2C port 512, an oscillator 519, and/or filters for power 517.

The breakout board 500 of 200 and a BLRB, such as those shown in FIGS. 5A, 5C and 5D, may be the same board in some embodiments. In other products, the BLRB may be a subset of a breakout board 500 with less functionality or with no functionality. In either functional arrangement (fully functional or partially functional), the PDUT may be further tested while powered up and functioning. By doing so, electrical connections between the components on the substrate of the PDUT, or in the substrate (e.g.,vias, etc.) may be monitored during the environmental tests. Accordingly, in accordance with the teachings of the present disclosure one “board” may be employed for both environmental testing and for product operation and emulation purposes. Currently two such boards are required, on for environmental testing and a separate one for operation and emulation purposes.

As described with respect to certain embodiments, the test board extends connections between the external connectors of a device and the associated mounting pad on the test board from beneath the device, and effectively moves this connection to the outer periphery of the test board. In certain aspects, the connections of the external connector locations at the corners and the center of the device are brought out to the edges of the test board for testing during environmental testing of the device. In addition, the test board can be mounted on a test apparatus for environmental testing of a device. The test apparatus supplies the test board with sources of power and grounds and connections to the test points on the board. The output(s) of the test board are then available at the interface of the board outputs and any additional test equipment needed to test the device and the integrity of its external connections. The outputs are a plurality of various signals, measurements and voltages, and may be adapted to be processed by automated test equipment or by a human interface or a combination of both.

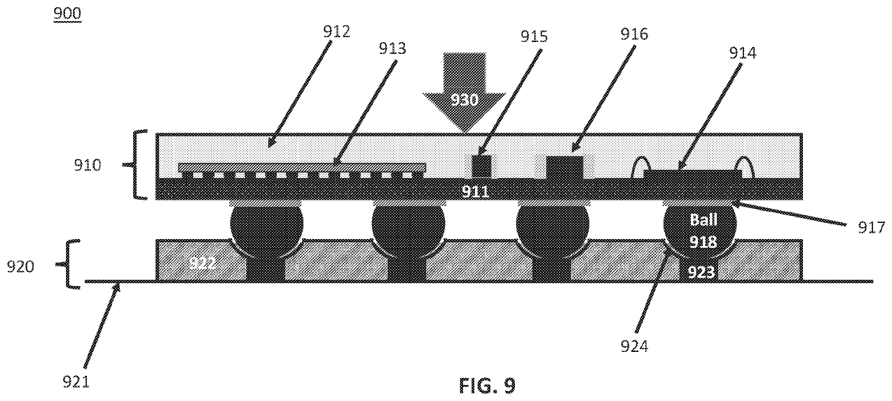

FIG. 9 depicts a testing setup 900 for production devices 910 according to embodiments. In certain aspects, the setup 900 may be employed in a production assembly line to perform environmental testing. In certain aspects, a device's 910 final test may include, but is not limited to, a combination of electrical, mechanical, and thermal tests in combination either sequentially or simultaneously. In the example of FIG. 9, the device 910 is pressed 930 into the load board 920 of a final-test apparatus. According to embodiments, the device 910 has a set of active components 913, 914 along with passive components 915, 916 electrically attached to the device substrate 911. Once assembled, it is encapsulated 912 and external connectors 918 attached. Once the device 910 is completely packaged, it is inserted into a load board 920 for its final test before shipping.

In some embodiments, the device 910 is inserted into a socket 922 on a printed circuit board 921 (e.g., part of the load board 920). Electrical contacts 923 in the socket 922 electrically connect the device to the test apparatus. Once electrically and structurally/mechanically attached to the load board 920, the test may begin. In this example, socket 922 has curved surface to partially anchor and support the balls during any mechanical vibration, so that any vibration is directed at the components inside the device being tested rather than the electrical connections between the external connections and the pads of the test board.

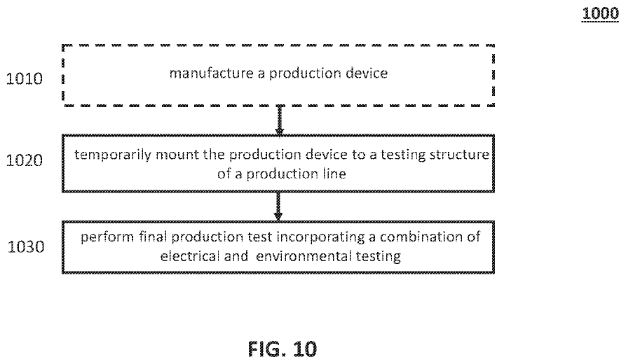

Referring now to FIG. 10, a process 1000 is illustrated according to some embodiments. The process may begin with step 1010, which may be optional in some embodiments. The process may be performed, for example, using one or more of the boards and setups shown and described with respect to FIGS. 5A-5D, 6A, 6B, 8, and 9. In step 1010 a production device is manufactured. In step 1020, the production device is mounted to a testing structure of a production line. In step 1030, a final test is performed with a combination of electrical and environmental components. In some embodiments, the mounting 1020 is temporary, such that the device may be easily removed (e.g., without the need for breaking physical connections) from the test structure at the conclusion of environmental testing. One form of temporary mounting may be through applied pressure.

According to embodiments, the production device of FIGS. 8 and 9 is a SIP.

### FURTHER EXAMPLES

In a first example, a board-level-reliability test board (BLRB) with strategically placed pad locations to connect with a plurality of external connectors of a production device under test (PDUT) is provided. In some embodiments, the external connectors are leaded, leadless, or balls in a grid (BGA). Additionally, there may be a selection of a subset of external connectors, all of which are electrically interconnected together by virtue of being on a single conducting plane inside the PDUT. In certain aspects, the conducting plane may be extended over multiple conductive layers of the PDUT's substrate. In certain aspects, a specially designed PCB can be used for capacitance between connectors on two different planes.

In a second example, a BLRB has metal conductors routed from previously, strategically selected and placed pads to another test connector location on the BLRB.

In a third example, a method of using a production device on the BLRB instead of using a custom-made test package (STDUT) is provided. This could include, for example, where the production device (PDUT) has a BGA, leaded, or leadless external connector arrangement.

A fourth example may include using any pair of pads that are on a common or interconnected power, ground, or signal plane to check for continuity during and after a stress test. This may be with or without power applied to the PDUT (e.g., using a functional or non-functional production device). In certain aspects, one of the pair is connected to a signal that is electrically connected to the other of the pair through a capacitor, resistor, or inductor.

A fifth example comprises using an internally available capacitance to check integrity of two sets of connectors on different planes where the two planes are connected to a known value capacitor inside the package.

A sixth example comprises having a production device powered up during testing, including structural (e.g. vibration) and thermomechanical stressing.

A seventh example is a method for evaluating connections between selected external connectors of a production device with their associated pads on a test board for both physical and electrical integrity during testing, wherein the selected external connectors are connected to a common ground or power plane (e.g., a partial conductive layer as one or more layers) inside the multilayered substrate of the production device. In some embodiments, the connectors of the production device are attached to the pads of the test board using the same method employed to attach production devices to their system board or PCB.

In some examples, a breakout board is used as a test fixture (e.g., having additional components added to test board to allow for powering and operating the production device during testing).

In an eighth example, a test board is provided for testing the integrity of the attachment of the external connectors of a production device to a test board, comprising: (i) a set of pads arranged on the surface of the test board in a configuration suitable for interfacing with and attaching to the external connectors of the production device, and (ii) multiple groups of test connectors arranged on the surface of the test board outside the profile of the package of the production device and arranged to be interconnected to selected pads of the set of pads on the surface of the test board, wherein the selected test connectors are connected to external connectors of the production device that are internally connected to individual and isolated electrically conductive layers or conductive pours inside the production device. In some embodiments, the electrical layers comprise one or more ground planes and one or more power planes. In some embodiments, the selected pads are arranged in the corners and center of the production device.

In a ninth example, a test board for an environmental testing apparatus (e.g. to test a production device) is provided that comprises: (i) a plurality of connector pads arranged on the surface of the test board for connecting with selected external connectors of a production device (PDUT) that are attached to select power, ground, or signal planes internal to the PDUT or otherwise provide a first preselected electrical function for the production device; (ii) a plurality of test points on said surface of said test board spaced apart from said plurality of connector pads, and (iii) a plurality of conductive traces for individually interconnecting each of said plurality of connector pads with a corresponding test point in said plurality of test points. In some embodiments, a plurality of conductors are used for interconnecting the test board to the testing apparatus (e.g., to get power and ground and test signals from the test apparatus to the board mounted on it). In some embodiments, the test board has the necessary external devices required to electrically power the PDUT during environmental test.

In a tenth example, a test board for testing a production device using an environmental testing apparatus is provided that comprises: (i) a first plurality of pads on the surface of the board for connecting with a first group of selected external connectors of said production device that represent electrical ground for the device; (ii) a first plurality of test points on said surface of said test board spaced apart from said first plurality of pads; (iii) a first plurality of conductors interconnecting each of said first plurality of pads with a corresponding test point in said first plurality of test points; (iv) a second plurality of pads on said surface of the board for connecting with a second group of selected external connectors of said production device that represent another different electrical category for the device; (v) a second plurality of test points on said surface of said test board spaced apart from said second plurality of pads; and (vi) a second plurality of conductors interconnecting each of said second plurality of pads with a corresponding test point in said second plurality of test points. In some embodiments, there is a third plurality of pads on the surface of the board for connecting with a third group of selected external connectors of said production device to provide electrical power to said production device. In some embodiments, there is an external controller that is electrically powered and connected to the production device under test (PDUT). In some embodiments, the external controller is a microprocessor, computer, microcontroller, etc. In some embodiments, there is a memory device that is electrically powered and connected to the production device under test (PDUT). In some embodiments, there is a communication device that is electrically powered and interconnected between the PDUT and an external controller. It may be wired (e.g., USB, JTAG, I2C, etc.), wireless (e.g., Bluetooth, WiFi, etc.), or optical.

In an eleventh example, a method is provided for testing a production device using an environmental testing apparatus, comprising: creating a test board having: (i) a plurality of connector pads on the surface of the test board for connecting with external connectors of a production device and connected to a plurality of test points, (ii) a plurality of test points on said surface of said test board spaced apart from said plurality of pads, and (iii) a plurality of conductive traces interconnecting each of said plurality of connector pads with a corresponding test point in said plurality of test points; using external connectors of said production device to be tested to attach the production device to said test board by attaching and connecting external connectors of said production device to said plurality of connector pads; performing environmental testing of said production device while performing selected electrical checks/tests (e.g., continuity, resistive, capacitive, inductive, voltage) between a plurality of preselected/selected/predetermined collections of said connector pads (test points) for checks/tests of the connection between the pads of said test board and said external connectors of said production device; and evaluating the results of said testing of the connections between the connector pads of said test board and said external connectors of said production device. In some embodiments, the production device under test is powered during the environmental testing, or is otherwise functioning during environmental test and communicating with external monitoring equipment (e.g., computer, test equipment, etc.).

In a twelfth example, a method for testing a production device using an environmental testing apparatus is provided, comprising: creating a test board having a plurality of pads on the surface of the board for connecting with external connectors of said production device, a plurality of test points on said surface of said production device spaced apart from said plurality of pads, a plurality of conductors interconnecting select plurality of pads with a corresponding test point in said plurality of test points; providing a production device having external connectors for operation; connecting said external connectors of said production device to said plurality of pads; selecting a first group of said test points for testing the connection between the pads of said test board and said external connectors of said production device associated with said test points while environmentally testing said production device; selecting a second group of said test points for testing the connection between the pads of said test board and said external connectors of said production device associated with said test points while environmentally testing said production device; and continuing to select groups of test points until a selected portion all combinations of said groups of test points have been selected.

One or more of the examples may be combined according to embodiments.

### SUMMARY OF EMBODIMENTS

(Group A Embodiments) A1. An environmental testing method for a production device comprising: attaching a production device to a board; and performing environmental testing on one or more of the production device or board.

A2. The method of A1, wherein the environmental testing comprises one or more of thermal, mechanical (e.g., vibration or shock), or pressure (e.g., atmosphere or altitude) testing.

A3. The method of A1 or A2, wherein the board comprises a plurality of test points (e.g., arranged such that attaching the production device to the board provides an electrical connection between external connectors of the production device and the test points).

A4. The method of any of A1-A3, further comprising: evaluating (e.g., using the test points) one or more electrical/mechanical connections between the production device (e.g., one or of its external connectors, such as balls of a BGA) and the board (e.g., at connection pads of the board).

A5. The method of A4, wherein evaluating the one or connections comprises testing a signal path (or any measurable electrical connection, such as pair-wise connections) between at least one test point (e.g., two or more test points) and the production device.

A6. The method of A5, wherein at least one of:
(i) the signal path comprises a ground plane and/or a power (e.g., VDD) plane of the production device;
(ii) the signal path comprises signal connections (e.g., input/output signals) of the production device;
(iii) the signal path comprises two or more of the ground plane, power plane, and signal connections of the production device;
(iv) the testing comprises measurement of an impedance (e.g., resistance);
(v) the testing comprises measurement of a capacitance or inductance;
(vi) the testing comprises measurement of a pull-up or pull-down resistor of the production device;
(vii) the evaluating is performed using more than two test points of the board;
(viii) the evaluation measures a series connection (e.g., a connection internal to the production device); and/or
(ix) the evaluation measures a parallel connection (e.g., a connection internal to the production device).

A7. The method of any of A3-A6, further comprising: using or producing a list that maps test points and corresponding external connectors of the production device.

A8. The method of A7, wherein the list further comprises an identifier associated with the test point, external connector, and/or path type.

A9. The method of any of A1-A8, further comprising: applying power to the production device.

A10. The method of any of A1-A9, further comprising: evaluating performance of the production device.

A11. The method of A9 or A10, wherein the power is applied using one or more (e.g., a plurality) of the test points of the board.

A12. The method of any of A1-A11, further comprising: measuring a signal generated in the production device (e.g., using the test points).

A13. The method of A12, wherein the signal is measured using one or more (e.g., a plurality) of the test points of the board.

A14. The method of any of A9-A13, wherein the production device is designed for a particular function (e.g., is a SIP), and the evaluating comprises testing performance of that function (e.g., testing for a selected operation).

A15. The method of any of A1-A14, wherein the method comprises testing a system of any of the Group C embodiments set forth below.

A16. The method of any of A1-A14, wherein the board is a test board according to any of the Group D embodiments set forth below.

A17. The method of any of A1-A14, wherein the board is a breakout board comprising one or more additional components mounted thereon (e.g., one or more additional components for operating or emulating the production device, controlling or assisting with evaluation of performance of the device, controlling or assisting with evaluation of a connection, communicating with the device, and/or storage).

A18. The method of A17, wherein the additional components comprise one or more of:
(i) a micro-SD card;
(ii) a micro-USB port;
(iii) a power or communications port;
(iv) a JTAG port;
(v) boot/EPROM memory for configuration of the production device;
(vi) test pin adapters;
(vii) a reset button;
(viii) LEDS;
(ix) an I2C port;
(x) an oscillator; and/or
(xi) one or more filters.

(Group B Embodiments) B1. A manufacturing method comprising: manufacturing a production device; mounting the production device on a testing structure of a production line (e.g., inserting onto a load board); and performing environmental testing on the mounted production device, wherein the mounting is a temporary mounting comprising non-permanent electrical and mechanical connections between the production device and the testing structure.

B2. The method of B1, wherein the testing structure comprises a socket (e.g., with one or more electrical contacts) on a board.

B3. The method of B1 or B2, further comprising: applying force to the production device to secure it within the testing structure.

B4. The method of any of B1-B3, further comprising performing any of the methods of the Group A embodiments described above.

(Group C Embodiments) C1. A system comprising: a test board; and a production device mounted to the test board.

C2. The system of C1, wherein the test board is adapted for environmental testing comprising one or more of thermal, mechanical (e.g., vibration or shock), or pressure (e.g., atmosphere or altitude) testing.

C3. The C1 or C2, wherein the test board comprises a plurality of test points, and wherein there are one or more electrical connections between external connectors of the production device and the test points.

C4. The system of C3, wherein the test points are adapted for evaluating one or more electrical and/or mechanical connections between the production device (e.g., one or more of its external connector) and the board (e.g., at connection pads of the board).

C5. The system of C4, wherein the external connectors of the production device comprise a plurality of BGA connectors.

C6. The system of any of C2-CS, wherein the test points provide connections between one or more external connectors at the center of, and at least one corner of, the production device.

C7. The system of any of C3-C6, further comprising: a signal path (or any measurable electrical connection, such as pair-wise connections) between at least two test points through the production device.

C8. The system of C7, wherein at least one of:
(i) the signal path comprises a ground plane and/or a power (e.g., VDD) plane of the production device;
(ii) the signal path comprises signal connections (e.g., input/output signals) of the production device;
(iii) the signal path comprises two or more of the ground plane, power plane, and signal connections of the production device;
(iv) the signal path indicates an impedance (e.g., resistance) within the production device;
(v) the signal path enables measurement of a capacitance or inductance within the production device;
(vi) the signal path includes a pull-up or pull-down resistor of the production device;
(vii) the signal path is between more than two test points of the board;
(viii) the signal path is a series connection; and/or
(ix) the signal path a parallel connection.

C9. The system of any of C1-C8 further comprising: at least one connection (e.g., a port) for applying power to the production device.

C10. The system of C9, wherein the power connection is one or more of the test points of the board.

C11. The system of any of C1-C10, further comprising: a signal connection (e.g., a port) for measuring/detecting/obtaining a signal generated in the production device.

C12. The system of C11, wherein the signal connection is one or more of the test points of the board.

C13. The system of any of C1-C12, wherein the production device is designed for a particular function (e.g., is a SIP having a SiP substrate with multiple layers for power (voltages), ground(s), and other types of signals, such as for example, but not limited to input signals, output signals, test signals, and control signals), and the system is adapted for testing the performance of that function.

C14. The system of any of C1-C13, wherein the test board comprises one or more of a memory and/or communications device or port.

C15. The method of any of C1-C14, wherein the board is a breakout board comprising one or more additional components mounted thereon (e.g., one or more additional components for operating or emulating the production device, controlling or assisting with evaluation of performance of the device, controlling or assisting with evaluation of a connection, communicating with the device, and/or storage).

C16. The system of C15, wherein the additional components comprise one or more of:
(i) a micro-SD card;
(ii) a micro-USB port;
(iii) a power or communications port;
(iv) a JTAG port;
(v) boot/EPROM memory for configuration of the production device;
(vi) test pin adapters,
(vii) a reset button;
(viii) LEDs;
(ix) an I2C port;
(x) an oscillator; and/or
(xi) one or more filters.

C17. The system of any of C1-C16, wherein the test board is a board according to any of the following Group D Embodiments set forth below.

(Group D Embodiments) D1. A test board comprising: a board (e.g., substrate); a plurality of connection pads (e.g., for mounting a production device); and a plurality of test points arranged for one or more of: (i) measurement of an electrical connection between the board and a production device; and/or (ii) measurement of a signal or function of a production device mounted on the board.

D2. The test board of D1, wherein the connection pads comprise: a first plurality of pads on the surface of the board (e.g., for connecting with a first group of external connectors of a production device) electrically connected with a first set of one or more of the test points; and a second plurality of pads on the surface of the board (e.g., for connecting with a second group of external connectors of the production device) electrically connected with a second set of one or more of the test points.

D3. The test board of D2, wherein the connection pads further comprise: a third plurality of pads on the surface of the board (e.g., for connecting with a third group of external connectors of a production device) electrically connected with a third set of one or more of the test points.

D4. The test board of D2 or D3, wherein respective pads and test points are interconnected using conductive traces on or within the board.

D5. The test board of any of D1-D4, further comprising: an external controller mounted on the board that is adapted to be electrically powered and connected to a production device under test.

D6. The test board of D5, wherein the external controller is a microprocessor, computer, or microcontroller.

D7. The test board of any of D1-D6, further comprising: a memory device that is adapted to be electrically powered and connected to the production device under test.

D8. The test board of any of D1-D7, further comprising: a communication device that is adapted to be electrically powered and interconnected between the production device under test and an external controller.

D9. The test board of D8, wherein:
(i) the communication device is wired (e.g., USB, JTAG, I2C)
(ii) the communication device is wireless (e.g., Bluetooth, WiFi, cellular)
(iii) the communication device is optical.

While the present disclosure has been described with respect to the embodiments set forth above, the present disclosure is not limited to these embodiments. Accordingly, other embodiments, variations, and improvements not described herein are not excluded from the scope of the present disclosure. Such variations include but are not limited to new substrate materials, various mechanical, electrical, and optical devices attached to the substrate not discussed, different operational or environmental testing requirements, different methods of attaching devices to a substrate or PCB, or new packaging concepts.

1-31. (canceled)

32. An environmental testing method for a production device comprising:
attaching a production device to a board; and
performing environmental testing on one or more of the production device or board, wherein the environmental testing comprises one or more of thermal, mechanical, or pressure testing.

33. The method of claim 32, wherein the board comprises a plurality of test points arranged such that attaching the production device to the board provides an electrical connection between external connectors of the production device and the test points.

34. The method of claim 32, further comprising:
evaluating one or more electrical or mechanical connections between the production device and the board.

35. The method of claim 34, wherein the evaluating one or more connections comprises testing a signal path between at least one test point and the production device.

36. The method of claim 35, further comprising:
using or producing a list that maps test points and corresponding external connectors of the production device.

37. The method of claim 36, wherein the list further comprises an identifier associated with the test point, external connector, or path type.

38. The method of claim 32, further comprising:
applying power to the production device.

39. The method of claim 38, further comprising:
evaluating performance of the production device.

40. The method of claim 38, wherein the power is applied using one or more test points of the board.

41. The method of claim 38, further comprising:
measuring a signal generated in the production device, wherein the signal is measured using one or more test points of the board.

42. The method of claim 39, wherein the production device is designed for a particular function, and the evaluating comprises testing performance of that function.

43. The method of claim 32, wherein the board is a test board comprising a substrate; a plurality of connection pads; and a plurality of test points arranged for one or more of: (i) measurement of an electrical connection between the board and the production device; or (ii) measurement of a signal or function of the production device mounted on the board.

44. The method of claim 32, wherein the board is a breakout board comprising one or more additional components mounted thereon, and wherein the additional components comprise one or more of:
(i) a micro-SD card;
(ii) a micro-USB port;
(iii) a power or communications port;
(iv) a JTAG port;
(v) boot/EPROM memory for configuration of the production device;
(vi) test pin adapters;
(vii) a reset button;
(viii) LEDs;
(ix) an I2C port;
(x) an oscillator; or
(xi) one or more filters.

45. The method of claim 32, wherein the attaching comprises applying force to the production device to secure it to a testing structure of the board.

46. The method of claim 32, wherein the attaching comprises performing a temporary mounting with non-permanent electrical and mechanical connections between the production device and the board.

47. The method of claim 46,
wherein the board comprises a testing structure having at least one socket, and
wherein the attaching comprises applying force to the production device to secure it to the at least one socket.

48. The method of claim 32, wherein the board comprises a mounting assembly containing a plurality of connection pads arranged for mounting thereon the production device and having a plurality of test pads individually interconnected with one of each of said plurality of connection pads.

49. A system for environmental testing of a production device, comprising:
a production device, wherein the production device is a packaged electrical device; and
a test board having a mounting assembly containing a plurality of connection pads arranged for mounting thereon the production device and having a plurality of test pads individually interconnected with one of each of said plurality of connection pads, wherein said test board is adapted for environmental testing;
wherein the production device comprises a plurality of external connectors mounted to the plurality of connection pads of the test board for testing the connections between the connection pads and the external connectors of the packaged electrical device while performing environmentally tests.

50. The system of claim 49, wherein the production device is mounted to the test board with non-permanent electrical and mechanical connections between the production device and the test board.

51. The system of claim 49, further comprising:
an external controller mounted on the test board, wherein the controller is adapted to be electrically powered and connected to the production device under test;
a memory device, wherein the memory device is adapted to be electrically powered and connected to the production device under test; and
a communication device, wherein the communication device is adapted to be electrically powered and interconnected between the production device under test and an external controller.
